(19) United States
(12) Patent Application Publication
(10) Pub. No.: US 2007/0205509 A1
(43) Pub. Date: Sep. 6, 2007

(54) SEMICONDUCTOR DEVICE WITH BATTERY

(75) Inventors: Kyong-Hee JOO, Gyeonggi-do (KR); In-Seok YEO, Seoul (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/465,906

(22) Filed: Aug. 21, 2006

(30) Foreign Application Priority Data
Feb. 22, 2006 (KR) 2006-17454

(51) Int. Cl. H01L 23/48

(52) U.S. Cl. 257/734

(57) ABSTRACT

An embodiment of a pseudo nonvolatile memory device incorporating a high capacity micro battery includes a DRAM chip having bonding pads. The DRAM chip may be attached to a frame. The frame may have external connecting terminals corresponding to the bonding pads. Wires are provided for electrically connecting the bonding pads to corresponding external connecting terminals. The bonding pads and the wires may be covered with an encapsulant. A micro battery is provided over the DRAM chip. The micro battery may supply power to the DRAM chip.

### CROSS REFERENCE TO RELATED APPLICATION

This application claims priority from Korean Patent Application No. 2006-17454, filed Feb. 22, 2006, the disclosure of which is hereby incorporated by reference herein in its entirety.

### FIELD OF THE INVENTION

The present invention relates to semiconductor device and, more particularly, to a package incorporating a small sized micro battery with an improved performance.

### BACKGROUND OF THE INVENTION

Both high integration and high speed of memory devices are required for multi-function and miniaturization of electronic equipment that use semiconductor devices. The memory devices are generally classified into volatile memory devices and non-volatile memory devices. While the volatile memory devices lose stored data when their power supply is cut off, the non-volatile memory devices continue to store their data even when their power supply is cut off.

Volatile memory devices can be further divided into DRAM (dynamic random access memory) and SRAM (static random access memory). A flash memory is widely used among the non-volatile memory devices. One may easily delete or write to flash memory. The flash memory, however, is limited to the number of times data can be both written and erased, and its operating speed is relatively slow compared to DRAM and SRAM.

SRAM generally has a fast operating speed and low power consumption compared to DRAM, but it has a structure that is disadvantageous in high integration.

DRAM is widely used for various electronic equipment because it has faster operating speed than flash memory, and higher integration than SRAM. The memory cell of DRAM consists of a transistor and a capacitor.

Electric charge stored in the DRAM's capacitor slowly leaks out, for various reasons, so that data stored in the memory cell of the DRAM may eventually disappear over extended periods of time. Accordingly, DRAM needs to have a refresh operation for preserving its stored data. Therefore, DRAM has relatively high power consumption compared to SRAM, due to the need for this refresh operation.

SRAM requires about 10 μA for standby current and DRAM requires about 200 μA for standby current.

A pseudo non-volatile memory has been studied for faster operation speed and longer data retention.

In implementing the pseudo non-volatile memory, subsidiary power may be continuously supplied to the volatile memory devices by using a micro battery when a main power supply is cut off. In this case, the micro battery should be small so it does not prevent the miniaturization of electronic equipment, and it should have plenty of power capacity to be able to supply subsidiary power needed for data retention.

A memory chip may be attached to a thin film battery within a package. The thin film battery may be arranged on a PCB board, and the memory chip may be arranged on the thin film battery. The thin film battery may be connected by bonding wire between a bonding pad on the memory chip and circuits on the PCB board. In this case, the bonding wire may be relatively long to make this connection. And, the relatively longer bonding wire may cause a deterioration of electrical characteristics, such as higher resistance.

Other technologies for implementing a pseudo non-volatile memory are disclosed, for example, in Japanese Laid-Open Publication No. 2005-18825A to Kihara Yuji, entitled “Semiconductor memory device” (hereafter Kihara).

According to Kihara, both a volatile memory and a second battery are connected in parallel. The second battery supplies a power to the volatile memory to keep data stored in the volatile memory when a main power supply is cut-off. There is a need, however, for improved technology for efficiently arranging both the volatile memory and the second battery.

### SUMMARY OF THE INVENTION

According to an embodiment of the invention, a pseudo nonvolatile memory device comprises a DRAM chip having bonding pads. The DRAM chip may be attached to a frame. The frame has external connecting terminals corresponding to the bonding pads. Wires may be provided for electrically connecting the external connecting terminals to the bonding pads. Both the bonding pads and the wires are coved with an encapsulant. A micro battery may be provided over the DRAM chip. The micro battery can supply power to the DRAM chip.

According to some embodiments of the invention, the micro battery is smaller than the size of the combined frame, DRAM chip and encapsulant. The micro battery may comprise a first current collector having a plurality of through holes; a first active material layer to cover both an inner wall of the through holes and at least a portion of the first current collector; a second active material layer opposing the first active material layer; and an electrolyte layer interposed between the first active material layer and the second active material layer. The second active material layer may fill the through holes. The first active material layer may cover both opposing sides of the first current collector.

According to other embodiment of the invention, the pseudo nonvolatile memory device comprises a first connector electrically connected to the first current collector, and a second connector electrically connected to the second active material layer.

According to still another embodiment of the invention, the micro battery is arranged inside the encapsulant.

According to still another embodiment of the invention, a semiconductor package incorporating a micro battery comprises a semiconductor chip having bonding pads. The semiconductor chip may be attached to a frame. The frame has external connecting terminals corresponding to each of the bonding pads. Wires may be provided for electrically connecting each of the bonding pads to each of the external connecting terminals. Both the bonding pads and the wires are covered with an encapsulant. A micro battery is provided over the semiconductor chip. The micro battery can supply power to the semiconductor chip. The micro battery may comprise a first current collector having a plurality of through holes; a first active material layer to cover both an inner wall of the through holes and at least a portion of the first current collector; a second active material layer opposing the first active material layer; and an electrolyte layer interposed between the first active material layer and the second active material layer.

According to some embodiments of the invention, the semiconductor chip comprises a volatile memory cell.

According to still another embodiment of the invention, the first current collector comprises one selected from the group consisting of nickel, aluminum, platinum, copper, and stainless steel.

According to still another embodiment of the invention, in case the first current collector comprises one selected from the group consisting of nickel and stainless steel, the first active material layer comprises one selected from the group consisting of Li, Graphite LiC, Al, LiAl, Si, LiSi, Sn, and LiSn. In this way, the second active material layer comprises one selected from the group consisting of LiCoO, LiNiO, LiMnO, and a-VO.

According to still another embodiment of the invention, the electrolyte layer comprises either LiPON or LiBO.

Some embodiments provide a second current collector contacting the second active material layer.

### BRIEF DESCRIPTION OF THE DRAWINGS

The invention is described below in relation to several embodiments illustrated in the accompanying drawings. Throughout the drawings like reference numbers indicate like exemplary elements, components, or steps, and the thickness of layers may be exaggerated for clarity.

FIG. 1 is a perspective view illustrating a micro battery according to an example embodiment.

FIG. 2 is a perspective view of region B of FIG. 1.

FIGS. 3 and 4 are perspective views to show portions of the micro battery according to an example embodiment.

FIG. 5 is a cross-sectional view taken along line I-I′ of FIG. 1.

FIGS. 6 to 8 are cross-sectional views taken along line II-II′ of FIG. 1.

FIG. 9 is a cross-sectional view illustrating an organization of a semiconductor package incorporating a micro battery according to an example embodiment.

FIG. 10 is a cross-sectional view taken along line III-III′ of FIG. 9.

FIG. 11 through FIG. 13 are cross-sectional views illustrating semiconductor packages incorporating a battery, according to other example embodiments.

### DESCRIPTION OF EXEMPLARY EMBODIMENTS

Exemplary embodiments of the invention are described below with reference to the corresponding drawings. These embodiments are presented as teaching examples. The actual scope of the invention is defined by the claims that follow.

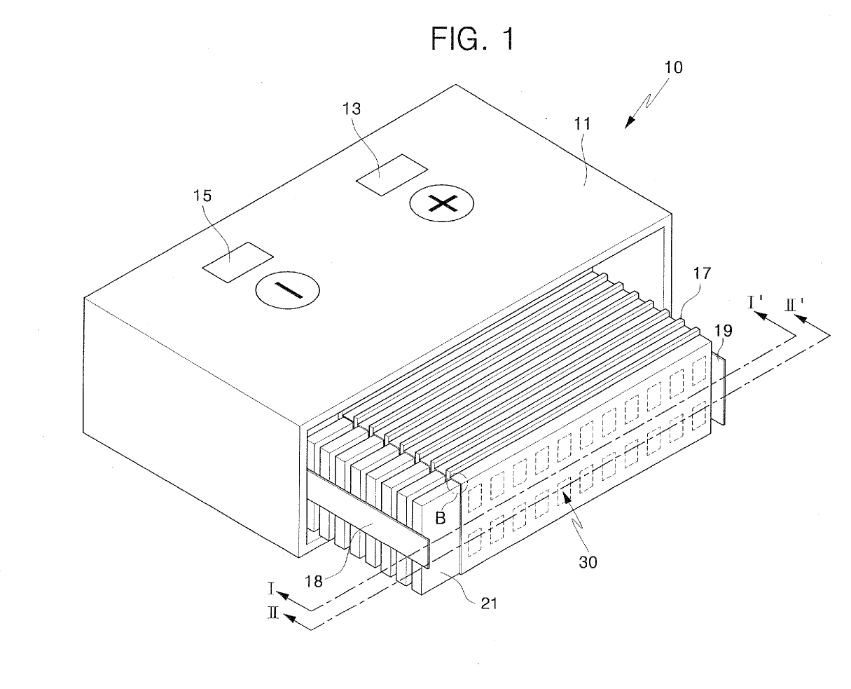

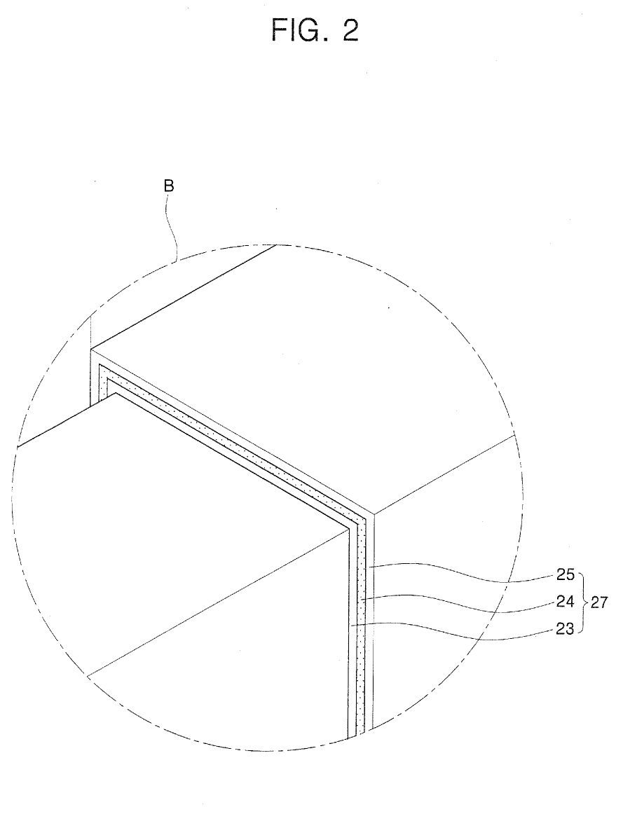

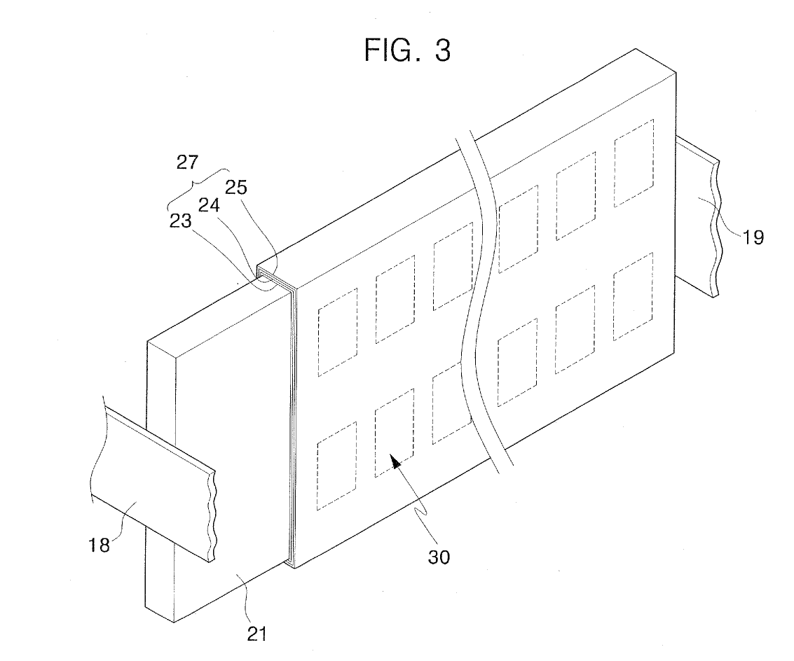

Referring to FIGS. 1 through 3, a first current collector 21 and a case 11 are provided. The first current collector 21 may be covered with an active material layer 23. An electrolyte layer 24 may also be formed on the first current collector 2 1. In turn, a second active material layer 25 may be provided on the electrolyte layer 24. A battery cell 27 may comprise stacked layers of the first active material layer 23, the electrolyte layer 24, and the second active material layer 25. T he second active material layer 25 contacts a second current collector 19. A plurality of the first current collectors 21 may be arranged in parallel within the case 11. A separator 17 may be arranged between the plurality of the first current collectors 21. The plurality of the first current collectors 21 may each be covered with the battery cell 27. That is, each of the plurality of the first collectors 21 may be covered with the first active material layer 23, the electrolyte layer 24, and the second active material layer 25, respectively. In this case, the second current collector 19 may be extended to contact each of the plurality of second active material layers 25. Each of the first current collectors 21 may be connected to each other by an electrode plate 18. The separator 17 comprises insulation material. In some embodiments the separator 17 may be omitted.

A positive electrode terminal 13 and a negative electrode terminal 15 are separately arranged in the case 11. The first current collectors 21 and the second current collectors 19 are arranged within the case I 1. The first current correctors 21 and the second current collectors 19 may act as conduits to carry an electric current of the battery cell 27. The first current collectors 21 may be electrically connected to the positive electrode terminal 13 by the electrode plate 18. And, the second current collector 19 may be electrically connected to the negative electrode terminal 15. On the contrary, the first current collectors 21 may be electrically connected to the negative electrode terminal 15 by the electrode plate 18, and the second current collector 19 may be electrically connected to the positive electrode terminal 13.

Referring to FIGS. 1 and 47 through holes 30 pass through the first current collector 21. The first current collector 21 may comprise one selected from the group consisting of nickel, aluminum, platinum, copper, and stainless steel. The first current collector 21 may be a conductive thin film with a thickness of about 1 μthrough 200 μm. The through holes 30 may be circular with a diameter of about 1 μm through 50 μm. The through holes 30 may also be rectangular or polygonal. The through holes 30 may be arranged in two directions along horizontal and vertical directions. The through holes 30 may have a diameter of about 15 um, for example, and be regularly arranged in the first current collector 21 having a thickness of about 80 μm. On the contrary, the through holes 30 may be arranged irregularly with various sizes.

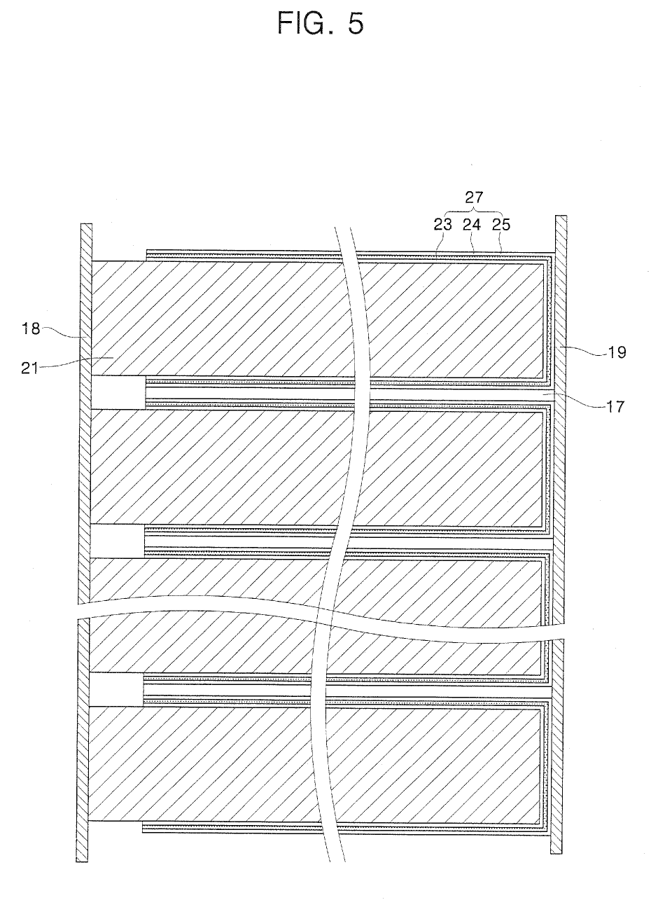

Referring to FIGS. 1 and 5, a sidewall of the first current collector 21 may contact the electrode plate 18. The electrode plate 18 may comprise conductive material. Other sidewalls of the first current collector 21 may be covered with the first active material layer 23. That is, the first active material layer 23 may cover the end of the first current collector 21 opposite the electrode plate 18 as well as two sidewalls of the first current collector 21.

The electrolyte layer 24 and the second active material layer 25 may be stacked on the first active material layer 23. The second active material layer 25 may contact the second current collector 19. As illustrated, a micro battery 10 according to one embodiment may provide a plurality of current collectors 21 arranged in parallel to each other. The second current collector 19 and the electrode plate 18 may also be arranged in parallel each other.

The first active material layer 23, the electrolyte layer 24, and the second active material layer 25 may each have a thickness of about 0.1 μm through 5 μm. The first active material layer 23, the electrolyte layer 24, and the second active material layer 25 may each have a thickness of about 3 μm, for example.

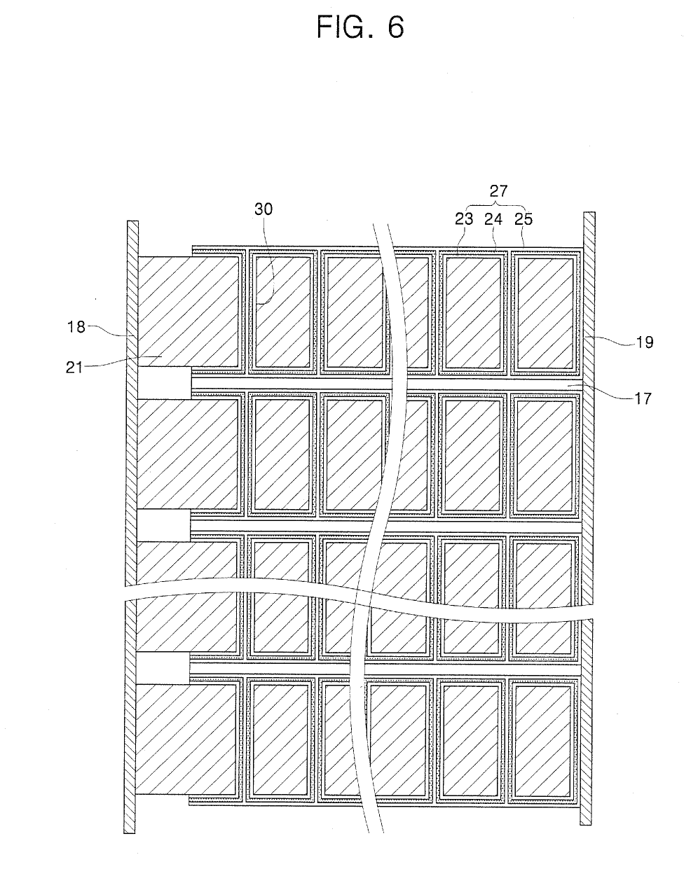

Referring to FIGS. 1 and 6, the first active material layer 23, the electrolyte layer 24, and the second active material layer 25 may be stacked on inside walls of the through holes 30. In this case, the first active material layer 23 may contact the first current collector 21, and the second active material layer 25 may fill the through holes 30. The electrolyte layer 24 may be interposed between the first active material layer 23 and the second active material layer 25.

As a result, the first active material layer 23 may cover the sidewalls of the first current collector 21, as well as the inside walls of the through holes 30. The second active material layer 25 may be arranged substantially parallel to the first active material layer 23 with the first electrolyte layer 24 interposed between.

The first active material layer 23 may be either a cathode or an anode. If the first active material layer 23 is a cathode, then the second active material layer 25 may be an anode. Or, if the first active material layer 23 is an anode, the second active material layer 25 may be a cathode. The electrolyte layer 24 may include LiPON or LiBO.

If the first active material layer 23 is a cathode, then the first active material layer 23 may include a material selected from the group consisting of LiCoO₂, LiNiO₂, LiNiO₂, and a-V₂O₅. The a-V₂O₅ means an amorphous V₂O₅. In this case, the second active material layer 25 may include a material selected from the group consisting of Li, graphite LiC₆, Al, LiAl, Si, Li₂Si, Li₄Si, Sn, and Li₂₂Sn₅.

Also, if the first active material layer 23 is a cathode, the first current collector 21 may include a material selected from the group consisting of nickel, aluminum and platinum. In this case, the second current collector 19 may include a material selected from the group consisting of copper and stainless steel.

On the contrary, if the first active material layer 23 is an anode, the first active material layer 23 may include one selected from the group consisting of Li, graphite LiC₆, Al, LiAl, Si, Li₂Si, Li₄Si, Sn, and Li₂₂Sn₅. In this case, the second active material layer 25 may include one selected from the group consisting of LiCoO₂, LiNiO₂, LiNiO₂, and a-V₂O₅.

Also, if the first active material layer 23 is an anode, the first current collector 21 may include one selected from the group consisting of copper and stainless steel. In this case, the second current collector 19 may include one selected from the group consisting of nickel, aluminum and white gold.

Table 1 shows the respective capacity of materials that are used as either the cathode or the anode.

TABLE 1
Capacity of Materials Used

| Electrode | Active material | | Capacity (uAh/Cm² · um) |
|---|---|---|---|
| Cathode | LiCoO₂ | | 75 |
| | LiNiO₂ | | 56 |
| | LiMnO₂ | | 63 |
| | a-V₂O₅ | | 100 |
| Anode | Li | | 200 |
| | Graphite LiC₆ | | 86 |
| | Al, LiAl | | 260 |
| | Si | Li₂Si | 445 |
| | | Li₄Si | 889 |

| | |
|---|---|
| Sn, Li₂₂Sn₅ | 725 |

As shown in TABLE 1, materials that are used in either the first active material layer 23 or the second active material layer 25 have different capacities. Also, the capacity of the battery cell 27 may be proportional to the volume of either the first active material layer 23 or the second active material layer 25, or both. Materials that are used in either the first active material layer 23 or the second active material layer 25 generally have lower electrical conductivities than that of either the first current collector 21 or the second current collector 19. Therefore, it may be advantageous to enlarge a contact area between the first current collector 21 and the first active material layer 23 to increase the capacity of the micro battery 10.

As mentioned earlier, the micro battery 10, according to the present embodiment, may provide the first current collector 21 that includes holes 30. The first active material layer 23 may cover sidewalls of the first current collector 21, and be extended to cover the inside walls of the through holes 30 of the first current collector 21. Therefore, contact area between the first current collector 21 and the first active material layer 23 can be dramatically increased by utilizing the surface area of the holes' inside walls, so that the capacity of the micro battery 10 may be increased compared to conventional technology. Thus, the micro battery 10 may have a relatively small size while having a high capacity.

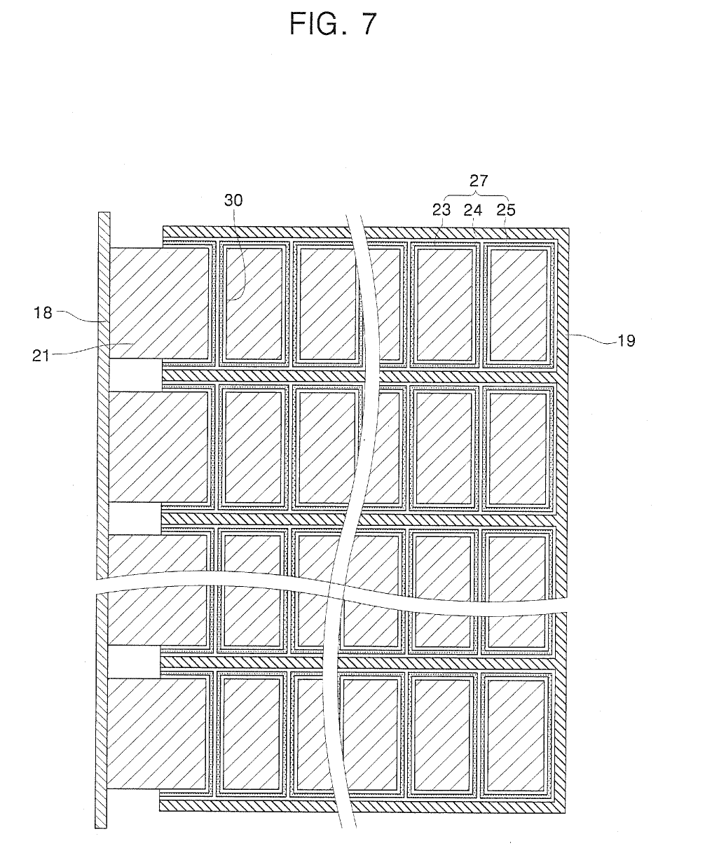

Referring to FIGS. 1 and 7, the second current collector 19 may be extended to cover the sidewalls of the first current collector 21.

To obtain a micro battery having high capacity, the contact area between the second current collector 19 and the second active material layer 25 may be increased by, for example, extending the second current collector 19 between the first current collectors 2 1, and around a corner of the first current collector 21 that is on the end of the first current collectors 21, as shown in FIG. 7. The battery cell 27 may be arranged between the first current collector 21 and the second current collector 19. In this case, the first active material layer 23 may contact the first current collector 21, and the second active material layer 25 may contact the second current collector 19. Therefore, the contact area between the second active material layer 25 and the second current collector 19 may be increased. The separator 17 may be omitted.

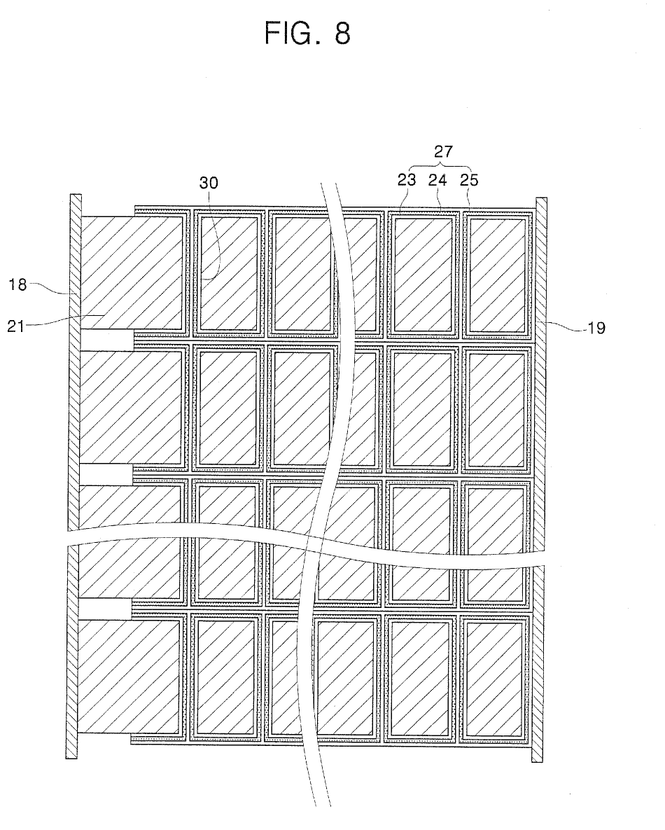

The separator 17 shown in FIG. 6 may be omitted, as shown in FIG. 8, to decrease the size of the micro battery.

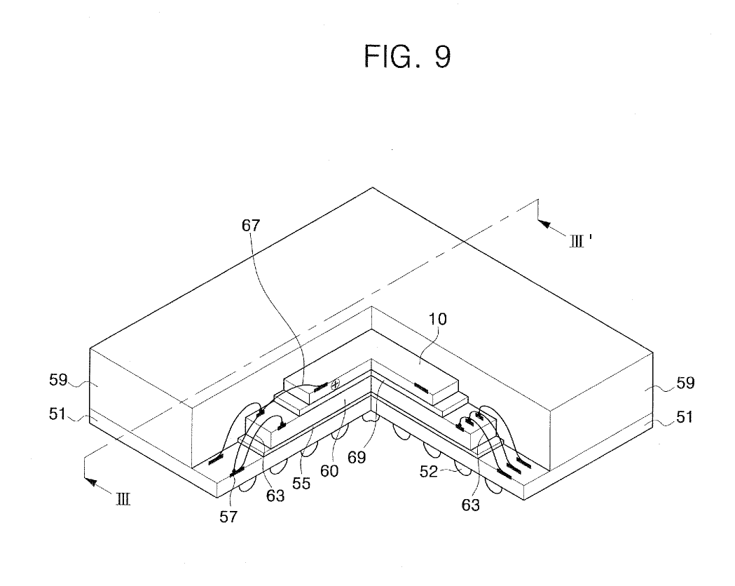

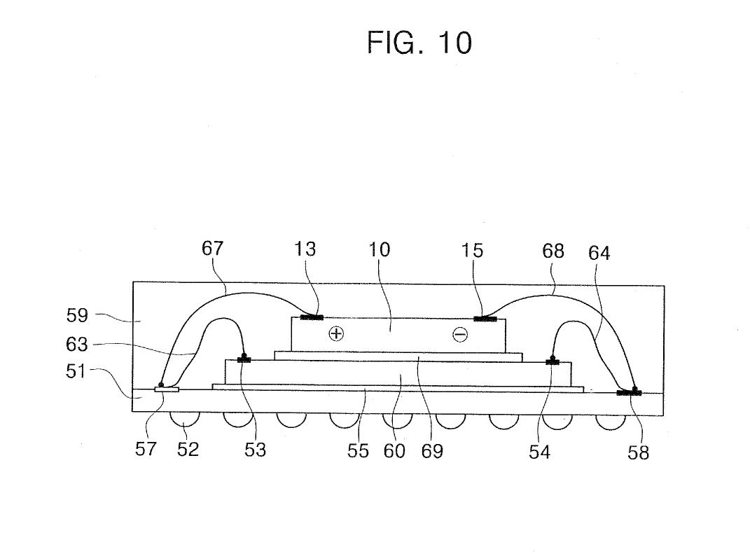

FIG. 9 is a partial perspective view illustrating an organization of a semiconductor package incorporating a micro battery according to an example embodiment. FIG. 10 is a cross-sectional view taken along line III-III′ of FIG. 9.

Referring to FIGS. 9 and 10, a semiconductor package may include a frame 51, a semiconductor chip 60, a micro battery 10, and an encapsulant 59. A semiconductor package incorporating the micro battery 10 may, for example, be a FBGA (fine pitch ball grid array).

The frame 51 may be a PCB (printed circuit board) or a PI (polyimide) board. The PI board has relatively flexible characteristics in comparison with the PCB. The frame 51 may include conductive balls 52 to connect to an external circuit. The conductive balls 52 may be arranged in two dimensions along both horizontal and vertical directions. The conductive balls 52 may be solder balls.

The frame 51 may include external connecting terminals 57 and 58. The external connecting terminals 57 and 58 may be arranged on either side of the frame 51. The external connecting terminals 57 and 58 may be electrically connected to one of the conductive balls 52.

The semiconductor chip 60 may be attached to the frame 51. Chip adhesive 55 may be interposed between the frame 51 and the semiconductor chip 60. The chip adhesive 55 may fix the semiconductor chip 60 on the frame 51. The semiconductor chip 60 may include a memory cell such as a DRAM cell.

Moreover, the semiconductor chip 60 may include bonding pads 53 and 54. The bonding pads 53 and 54 may be electrically connected to external connecting terminals 57 and 58 by wires 63 and 64. The wires 63 and 64 may be gold or aluminum wire. The first bonding pad 53 may be connected to the external connecting terminal 57 by the first wire 63, and the second bonding pad 54 may be connected to the second external connecting terminal 58 by the second wire 64. The first bonding pad 53 may be a Vdd terminal, and the second bonding pad may be a Vss terminal, for example.

The micro battery 10 may be arranged on the semiconductor chip 60. A battery adhesive 69 may be interposed between the micro battery 10 and the semiconductor chip 60. The battery adhesive 69 may fix the micro battery 10 to the semiconductor chip 60. The battery adhesive 69 may include insulation material.

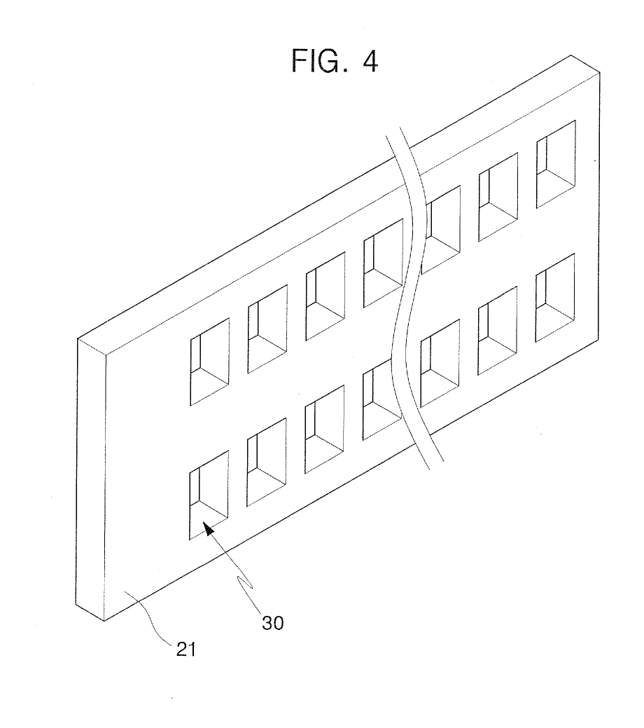

As illustrated in FIGS. 1 through 8, the micro battery 10 may include the first current collector 21, the first active material layer 23, the electrolyte layer 24, the second active material layer 25, and the second current collector 19.

The micro battery 10 may be electrically connected to the external connecting terminals 57 and 58 by a first connector 67 and a second connector 68. The first connector 67 and the second connector 68 may also be Au or aluminum wire. The first external connecting terminal 57 may be electrically connected to the positive electrode terminal 13 by the first connector 67. Moreover, the first external connecting terminal 57 may be directly connected to either the first current collector 21 or the second current collector 19 by the first connector 67. The second external connecting terminal 58 may be electrically connected to the negative electrode terminal 15 by the second connector 58. The second external connecting terminal 58 may be directly connected to either the first current collector 21 or the second current collector 19 by the second connector 68.

The encapsulant 59 may be provided on the frame 51. The encapsulant 59 may be an epoxy molding compound. The encapsulant 59 may cover the micro battery 10, the semiconductor chip 60, the first connector 67, the second connector 68, the wires 63 and 64, the bonding pads 53 and 54, and the external connecting terminals 57 and 58. The micro battery 10 may have a smaller size than each of the frame 51, the semiconductor chip 60, and the encapsulant 59.

The micro battery 10 may supply power to the semiconductor chip 60. The semiconductor chip 60 may include a volatile memory cell such as a DRAM cell. The semiconductor chip 60, for example, may be a DRAM chip or an SRAM chip. When a supply of main power is cut off from the volatile memory cell, the micro battery 10 may supply a subsidiary power for preserving data stored in the volatile memory cell.

On the other hand, a semiconductor package having a conventional thin film battery generally has a structure of a semiconductor chip on the thin film battery. In this case, wires connecting the semiconductor chip to external connecting terminals have to be relatively extended depending on the size of the thin film battery. Therefore, the wire for connecting the semiconductor chip to external connecting terminals may cause efficiency and reliability problems.

According to another embodiment of the invention, the micro battery 10, may be arranged on the semiconductor chip 60 to not obstruct an efficient arrangement of the wires 63 and 64.

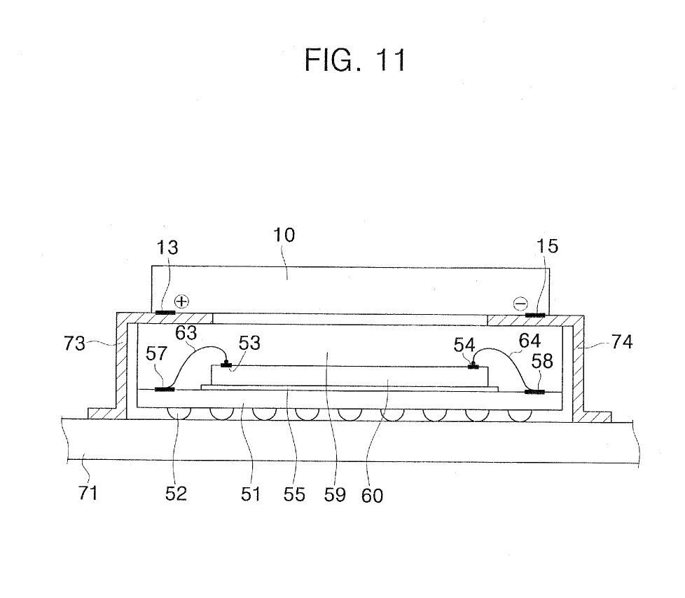

FIGS. 11 through 13 are cross-sectional views illustrating semiconductor packages incorporating a battery according to other embodiments.

Referring to FIG. 11, a semiconductor package may include a frame 5 1, semiconductor chip 60, an encapsulant 59, a first connector 73, a second connector 74, and a micro battery 10.

The frame 51 may include conductive balls 52 for connecting to an external circuit, and external connecting terminals 57 and 58. The conductive balls may be arranged on the lower surface of the frame 51, and the external connecting terminals 57 and 58 may be electrically connected to one of the conductive balls 52. The semiconductor chip 60 may be attached to the frame 51. Chip adhesive 55 may be interposed between the frame 51 and the semiconductor chip 60. The semiconductor chip 60 may include a volatile memory cell such as a DRAM cell or an SRAM cell.

Moreover, the semiconductor chip 60 may include bonding pads 53 and 54. The bonding pads 53 and 54 may be electrically connected to the external connecting terminals 57 and 58 by wires 63 and 64. The encapsulant 59 may be disposed on the frame 5 1. The encapsulant 59 may cover the semiconductor chip 60, the wires 63 and 64, the bonding pads 53 and 54, and the external connecting terminals 57 and 58.

The frame 51 may be attached to a system board 71. The system board may include a PCB. In this case, the external connecting terminals 57 and 58 may be electrically connected to the system board 71 by corresponding conductive balls 52.

The micro battery 10 may be attached to the encapsulant 59. The first connector 73 and the second connector 74 may be arranged to outside of the encapsulant 59. The first connector 73 may be electrically connected to the positive electrode terminal 13. The second connector 74 may be electrically connected to the negative electrode terminal 15. Both the first connector 73 and the second connector 74 may include materials having superior conductivity such as a copper lead frame or an alloy-42 lead frame. The first connector 73 and the second connector 74 may electrically connect the micro battery 10 to the system board 71. In other words, the micro battery 10 may be electrically connected to the external connecting terminals 57 and 58 by both the first connector 73 and the second connector 74.

The micro battery 10, the first connector 73 and the second connector 74 may be arranged completely or partially outside of the encapsulant 59. In this way, the micro battery 10 may easily avoid obstructing an efficient arrangement of the wires 63 and 64.

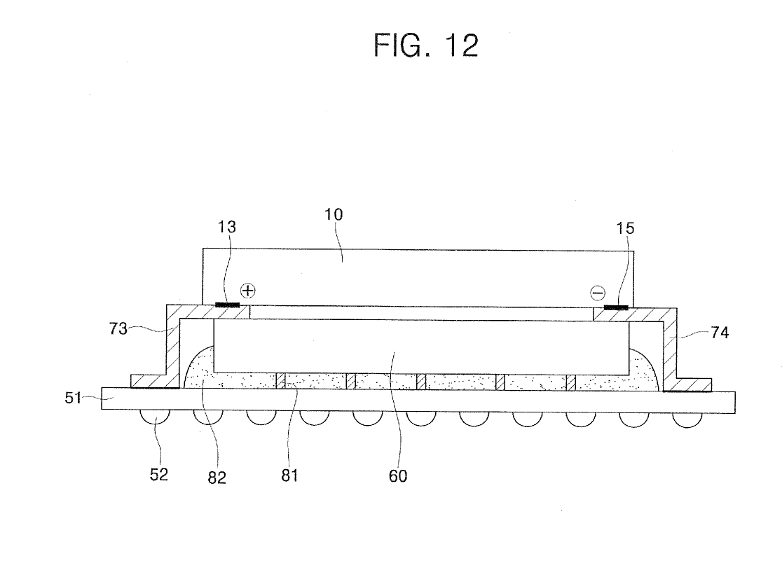

Referring to FIG. 12, a semiconductor package incorporating a battery, according to still another embodiment, may include a frame 51, semiconductor chip 60, an encapsulant 59, a first connector 73, a second connector 74, and a micro battery 10. The frame 51, the semiconductor chip 60, and the encapsulant 82 may consist of a flip chip package.

The frame 51 may include conductive balls 52 for connecting to an external circuit. The frame 51 may include external connecting terminals (not shown). Each of the external connecting terminals may be electrically connected to one of the conductive balls 52, respectively. The semiconductor chip 60 may be attached to the frame 51. The semiconductor chip 60 may include a volatile memory cell such as a DRAM cell or an SRAM cell. Moreover, the semiconductor chip 60 may include bonding pads (not shown).

Wires 81 may be arranged between the frame 51 and the semiconductor chip 60. The wires 81 may be either a solder bump or a gold bump. The wires 81 may electrically connect the bonding pads to the external connecting terminals. The encapsulant 82 may be interposed between the frame 51 and the semiconductor chip 60. The encapsulant 82 may cover the wires 81, the external connecting terminals, and the bonding pads. In this case, the backside of the semiconductor chip 60 may protrude from the exterior of the encapsulant 82.

The micro battery 10 may be arranged on the protruded backside of the semiconductor chip 60. The first connector 73 and the second connector 74 may be arranged to the exterior of the semiconductor chip 60 and the encapsulant 82. Both the first connector 73 and the second connector 74 may electrically connect the micro battery 10 to the frame 51.

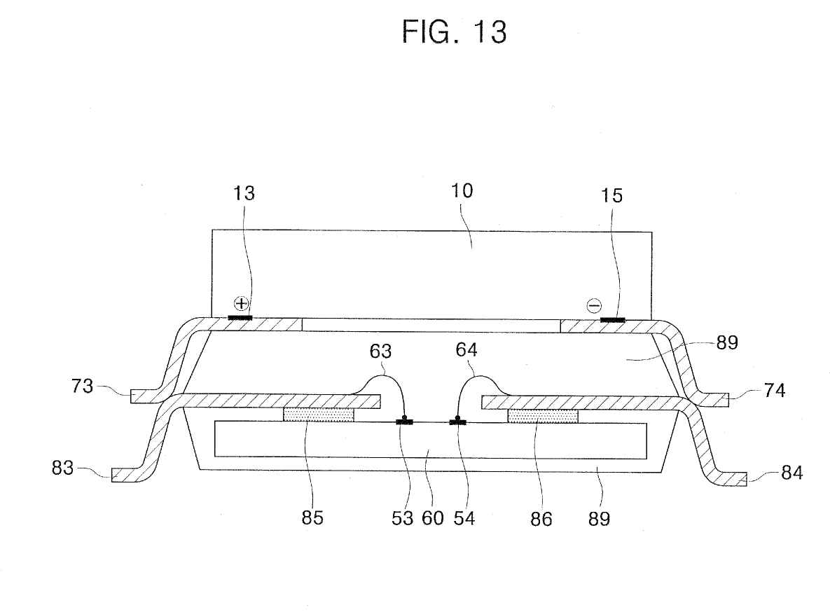

Referring to FIG. 13, a semiconductor package incorporating a battery, according to still another embodiment, may include frames 83 and 84, semiconductor chip 60, an encapsulant 89, a first connector 73, a second connector 74, and a micro battery 10. The frames 83 and 84, the semiconductor chip 60, and the encapsulant 89 may comprise a TSOP (thin small outline package).

The frames 83 and 84 may be a lead frame having a first external connecting terminal 83 and a second external connecting terminal 84. The lead frame, for example, may include fifty-four external connecting terminals 83 and 84. The semiconductor chip 60 may be attached to the first current collectors a lower surface of the frames 83 and 84. Chip adhesives 85 and 86 may be interposed between the semiconductor chip 60 and the frames 83 and 84. The chip adhesives 85 and 86 may include LOC (lead On Chip) tape. The chip adhesives 85 and 86 may fix the semiconductor chip 60 to the frames 83 and 84. The memory chip 60 may include a volatile memory cell such as a DRAM cell.

Moreover, the semiconductor chip 60 may include bonding pads 53 and 54. The bonding pads 53 and 54 may electrically connect to the external connecting terminals 83 and 84 by wires 63 and 64. The encapsulant 89 may cover all of the semiconductor chip 60, the wires 63 and 64, the bonding pads 53 and 54, the chip adhesives 85 and 86, and the frames 83 and 84. The external connecting terminals 83 and 84 may be extended to protrude from the exterior of the encapsulant 89.

The micro battery 10 may be arranged on the encapsulant 89. Both the first connector 73 and the second connector 74 may be arranged to the exterior of the encapsulant 59. Both the first connector 73 and the second connector 74 may electrically connect the micro battery 10 to the external connecting terminals 83 and 84. The micro battery 10 may easily avoid obstructing an efficient arrangement of the external connecting terminals 83 and 84 and the wires 63 and 64.

In conclusion, some embodiments include a nonvolatile memory incorporating a micro battery that has a large capacity with a relatively small size.

What is claimed is:

1. A pseudo nonvolatile memory device, comprising:
a DRAM chip having bonding pads;
a frame having external connecting terminals that correspond to the bonding pads, the frame attached to the DRAM chip;
wires for electrically connecting the external connecting terminals to the bonding pads, respectively; and
a micro battery for supplying power to the DRAM chip, which is positioned over the DRAM chip.

2. The pseudo nonvolatile memory device of claim 1, wherein the micro battery has a smaller size than an aggregated one of the frame and the DRAM chip.

3. The pseudo nonvolatile memory device of claim 1, wherein the micro battery comprises:
a first current collector having a plurality of through holes;
a first active material layer to cover both inner walls of the through holes and at least a portion of the first current collector;
an electrolyte layer on the first active material layer; and
a second active material layer on the electrolyte layer.

4. The pseudo nonvolatile memory device of claim 3, wherein the second active material layer fills the through holes.

5. The pseudo nonvolatile memory device of claim 3, wherein the first active material layer covers both opposing sides of the first current collector.

6. The pseudo nonvolatile memory device of claim 3, further comprising:
a first connector electrically connected to the first current collector; and
a second connector electrically connected to the second active material layer.

7. The pseudo nonvolatile memory device of claim 1, wherein the micro battery is arranged inside of an encapsulant that covers both the bonging pads and the wires.

8. A semiconductor package incorporating a micro battery comprising:
a semiconductor chip having bonding pads;
a frame having external connecting terminals corresponding to each of the bonding pads, the frame attached to the semiconductor chip,
wires electrically connecting the bonding pads to the external connecting terminals; and
a micro battery for supplying power to the semiconductor chip that is positioned over the semiconductor chip,
the micro battery comprising:
a first current collector having a plurality of through holes;
a first active material layer to cover inner walls of the through holes and at least a portion of the first current collector;
an electrolyte layer disposed on the first active material layer; and
a second active material layer disposed on the electrolyte layer.

9. The semiconductor package incorporating the micro battery of claim 8, wherein the semiconductor chip includes a volatile memory cell.

10. The semiconductor package incorporating the micro battery of claim 8, wherein the second active material layer fills the through holes.

11. The semiconductor package incorporating the micro battery of claim 8, wherein the first active material layer covers both opposing sides of the first current collector.

12. The semiconductor package incorporating the micro battery of claim 8, further comprising:
a first connector electrically connected to the first current collector; and
a second connector electrically connected to a second current collector that is connected to the second active material layer.

13. The semiconductor package incorporating the micro battery of claim 8, wherein the first current collector comprises one selected from the group consisting of nickel, aluminum, platinum, copper, and stainless steel.

14. The semiconductor package incorporating the micro battery of claim 13, wherein
the first active material layer comprises one selected from the group consisting of Li, Graphite LiC, Al, LiAl, Si, LiSi, Sn, and LiSn; and
the second active material layer comprises one selected from the group consisting of LiCoO, LiNiO, LiMnO and a-VO.

15. The semiconductor package incorporating the micro battery of claim 8 wherein the electrolyte layer comprises either LiPON or LiBO.

16. A micro battery comprising:
a first current collector having a plurality of through holes;
a first active material layer to cover both at least a portion of the first current collector and an inner wall of the through holes;
an electrolyte layer on the first active material layer; and
a second active material layer on the electrolyte layer.

17. The micro battery of claim 16, wherein the second active material layer fills the through holes.

18. The micro battery of claim 16, wherein the first active material layer covers both opposing sides of the first current collector.

19. The micro battery of claim 16, wherein the first current collector comprises one selected from the group consisting of nickel, aluminum, platinum, copper, and stainless steel.

20. The micro battery of claim 19, wherein
the first current collector comprises one selected from the group consisting of the nickel, the aluminum, and the platinum;
the first active material layer comprises one selected from the group consisting of LiCoO, LiNiO, LiMnO, and a-VO; and
the second active material layer comprises one selected from the group consisting of Li, Graphite LiC, Al, LiAl, Si, LiSi, Sn, and LiSn.

21. The micro battery of claim 19, wherein
the first active material layer comprises one selected from the group consisting of Li, Graphite LiC, Al, LiAl, Si, LiSi, Sn, and LiSn; and
the second active material layer comprises one selected from the group consisting of LiCoO, LiNiO, LiMnO, and a-VO.

22. The micro battery of claim 16, wherein the electrolyte layer comprises either LiPON or LiBO.

23. The micro battery of claim 16, further comprising a second current collector contacting the second active material layer.

24. A micro battery that includes a battery unit comprising:
a first current collector extending in a plane in a first direction, electrically connected to one of a positive or negative terminal;
through holes disposed in, and substantially perpendicular to, the plane of the first current collector to form inside surfaces thereof, and
a battery cell disposed on the first current collector and inside surfaces of the through holes, the battery cell electrically connected between the positive and negative terminals.

25. The micro battery of claim 24, wherein the battery cell comprises:
a first active material layer contacting at least a portion of the first current collector and the inside surfaces of the through holes;
an electrolyte layer on the first active material layer; and
a second active material layer on the electrolyte layer electrically connected to an opposite one of the positive or negative terminals to which the first current collect is connected to.

26. The micro battery of claim 25, further comprising a plurality of battery units arranged in planes parallel to one another, the first current collector of each of the battery units electrically connected to the one of the positive or negative terminal, and the second active material layer electrically connected to the opposite one of the positive or negative terminal.

27. The micro battery of claim 25, further comprising insulating separators disposed between the battery units.

28. The micro battery of claim 24, further comprising a case to enclose the micro battery.

29. The micro battery of claim 24, wherein the through holes are arranged in horizontal and vertical rows.

30. The micro battery of claim 26, wherein a second current collector electrically connected to the second active material layer and the other one of the positive or negative terminal is disposed to cover at least a portion of ends of the battery units and disposed between the battery units.
